(19) United States
(12) Patent Application Publication
(10) Pub. No.: US 2021/0075189 A1
(43) Pub. Date: Mar. 11, 2021

(54) SURFACE-EMITTING LASER STRUCTURE WITH HIGH HEAT DISSIPATION

(71) Applicant: HIGH POWER OPTO. INC., Taichung (TW)

(72) Inventors: Chih-Sung Chang, TAICHUNG (TW); Wei-Yu Yen, TAICHUNG (TW); Li-Ping Chou, TAICHUNG (TW); Li-Jun Lai, TAICHUNG (TW); Yi-Wun Sie, TAICHUNG (TW)

(21) Appl. No.: 16/567,223

(22) Filed: Sep. 11, 2019

(51) Int. Cl. H01S 5/024; H01S 5/187; H01S 5/32

(52) U.S. Cl. CPC H01S 5/02476; H01S 5/2214; H01S 5/32; H01S 5/187

(57) ABSTRACT

The present invention comprises a thermally-conductive and electrically-conductive substrate, a bonding layer, a galvanic isolation layer, a P-type electrode, a P-type Bragg reflection layer, a diode light-emitting layer, an N-type Bragg band-pass reflection layer and an N-type electrode stacked in sequence. The galvanic isolation layer comprises a cylindrical opening for accommodating the diode light-emitting layer. The N-type electrode comprises a light-output opening facing the cylindrical opening and completely covering the cylindrical opening. When current input by the N-type electrode passes through the N-type Bragg band-pass reflection layer, it is concentrated under constraint of the galvanic isolation layer and passes through the diode light-emitting layer via the cylindrical opening according to correspondence in position and size of the cylindrical opening and the light-output opening. Thus, light-emitting efficiency, response speed, and the effective light-emitting area are increased effectively, without use of an oxidized metal layer.

### FIELD OF THE INVENTION

The present invention relates to a surface-emitting laser structure, in particular to a surface-emitting laser structure about high heat dissipation.

### BACKGROUND OF THE INVENTION

Surface Emitting Laser (SEL) is a semiconductor structure in which laser is emitted vertically from the top surface, for example, is shown as Taiwan Patent No. I268031 “Vertical Cavity Surface Emitting Laser and Method for Fabricating the Same” and Taiwan Patent No. I403050 “Vertical Cavity Surface Emitting Laser (VCSEL), VCSEL Array Device, Optical Scanning Apparatus, and Image Forming Apparatus”.

Referring to FIG. 1, a conventional surface-emitting laser structure is shown, which comprises an N-type electrode 1, a substrate 2, an N-type Bragg reflection layer 3, a diode light-emitting layer 4, a current constraint layer 5, a P-type Bragg band-pass reflection layer 6, an isolation layer 7, a P-type electrode 8 and an anti-reflection (AR) layer 9. The N-type Bragg reflection layer 3 and the P-type Bragg band-pass reflection layer 6 have a high reflectance (optimal value: 100% reflection) to form a resonant cavity, and incident light of a specific wavelength interval is allowed to pass through the P-type Bragg band-pass reflection layer 6. Therefore, excitation light generated by the diode light-emitting layer 4 is repeatedly reflected between the N-type Bragg reflection layer 3 and the P-type Bragg band-pass reflection layer 6, and the excitation light is resonated with the diode light-emitting layer 4. Incident light that conforms to a specific wavelength interval is emitted through the P-type Bragg band-pass reflection layer 6, thereby forming surface-emitting laser.

According to the conventional surface-emitting laser structure, since it is required to set the current constraint layer 5, which is selected by a non-conductive oxidized metal, and the current constraint layer 5 is used to control the current direction, so as to increase the current density to make components more easily emit laser light. However, the current constraint layer 5 is an inactive area that current does not flow through this area, a laser emission source that can be accommodated in the area per unit area is limited. As a result, it is difficult to meet the demand on high current input and high brightness output, and the maximum output power of laser is reduced. In addition, the use of oxidized metal requires a wet oxidation process, resulting in a large variation in process and difficulty to effectively improve the process yield.

### SUMMARY OF THE INVENTION

A main objective of the present invention is to provide a surface-emitting laser structure with high heat dissipation, which comprises a relatively large effective light-emitting area and relatively high heat dissipation efficiency, and can meet the use requirements on high-power laser.

The present invention relates to a surface-emitting laser structure with high heat dissipation, comprising a thermally-conductive and electrically-conductive substrate, a bonding layer, a galvanic isolation layer, a P-type electrode, a P-type Bragg reflection layer, a diode light-emitting layer, an N-type Bragg band-pass reflection layer, an N-type electrode and an anti-reflection layer. The bonding layer is disposed on the thermally-conductive and electrically-conductive substrate, the galvanic isolation layer is disposed on the bonding layer, and comprises a cylindrical opening. The P-type electrode is disposed in the cylindrical opening and located on the bonding layer, the P-type Bragg reflection layer is disposed on the P-type electrode and located in the cylindrical opening. Further, the diode light-emitting layer is located in the cylindrical opening, and is disposed on the P-type Bragg reflection layer. The N-type Bragg band-pass reflection layer is disposed on the diode light-emitting layer, fills the cylindrical opening and covers the galvanic isolation layer. Moreover, the N-type electrode is disposed on the N-type Bragg band-pass reflection layer, and comprises a light-output opening facing the cylindrical opening, a projection of the light-output opening completely covering the cylindrical opening. Further, the anti-reflection layer is disposed on the N-type Bragg band-pass reflection layer and covers the N-type electrode to form the light-output opening.

Therefore, when a current input by the N-type electrode passes through the N-type Bragg band-pass reflection layer, the current is concentrated under the constraint of the galvanic isolation layer and passes through the diode light-emitting layer via the cylindrical opening, according to a correspondence relationship in position and size of the cylindrical opening and the light-output opening. Thus, a current constraint effect is achieved, and the light-emitting efficiency and the response speed are increased effectively. Compared with the prior art, a current constraint effect is achieved by the surface-emitting laser structure of the present invention without the use of oxidized metal. Therefore, the effective light-emitting area is increased. In addition, since the bonding layer is bonded to the thermally-conductive and electrically-conductive substrate, the heat dissipation effect is improved effectively by the high heat conductivity of the thermally-conductive and electrically-conductive substrate, and thus the usage requirements on high-current laser of laser with high power is met.

### BRIEF DESCRIPTION OF THE DRAWINGS

FIG. 1 is a sectional view of a conventional surface-emitting laser structure.

FIG. 2 is a structural sectional view of a surface-emitting laser structure of the present invention.

FIGS. 3A, 3B, 3C, 3D, and FIG. 3E are structural diagrams of a manufacturing process of the present invention.

FIG. 4 is a structural schematic diagram of the surface-emitting laser structure with high heat dissipation in plan view of the present invention.

FIG. 5 is a schematic diagram of current and light output of the surface-emitting laser structure of the present invention.

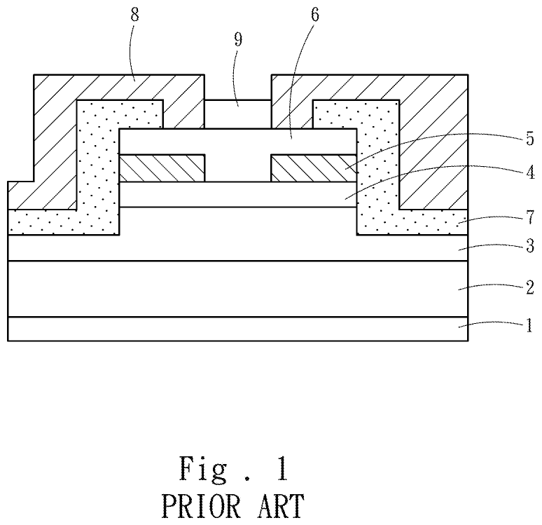

### DETAILED DESCRIPTION OF THE PREFERRED EMBODIMENTS

In order to have a better understanding and recognition of the features, objects and effects of the present invention, a preferred embodiment is illustrated in conjunction with the following description.

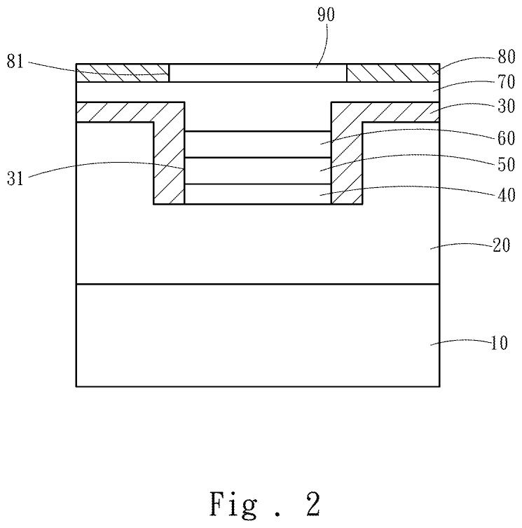

As shown in FIG. 2, the present invention provides a surface-emitting laser structure with high heat dissipation, which comprises a thermally-conductive and electrically-conductive substrate 10, a bonding layer 20, a galvanic isolation layer 30, a P-type electrode 40, a P-type Bragg reflection layer 50, a diode light-emitting layer 60, an N-type Bragg band-pass reflection layer 70 and an N-type electrode 80, wherein the bonding layer 20 is disposed on the thermally-conductive and electrically-conductive substrate 10, the galvanic isolation layer 30 is disposed on the bonding layer 20, and the galvanic isolation layer 30 comprises a cylindrical opening 31. The bonding layer 20 may be made of In or Ti/Au, the galvanic isolation layer 30 may be made of Ta₂O₃, SiO₂ or TiO₂, and the thermally-conductive and electrically-conductive substrate 10 may be a copper substrate.

The P-type electrode 40 is disposed on the bonding layer 20 and located in the cylindrical opening 31, and the P-type Bragg reflection layer 50 is disposed on the P-type electrode 40 and located in the cylindrical opening 31. Also, the diode light-emitting layer 60 is located in the cylindrical opening 31, and is disposed on the P-type Bragg reflection layer 50. Further, the N-type Bragg band-pass reflection layer 70 is disposed on the diode light-emitting layer 60, fills the cylindrical opening 31 and covers the galvanic isolation layer 30. The N-type Bragg band-pass reflection layer 70 and the P-type Bragg reflection layer 50 are a multilayer structure consisting of different structures, respectively, may be made of Ta₂O₃/SiO₂, TiO₂/SiO₂ or the like, and are formed by stacking according to usage demands.

As shown in FIG. 2, the N-type electrode 80 is disposed on the N-type Bragg band-pass reflection layer 70, and comprises a light-output opening 81 facing the cylindrical opening 31, a projection of the light-output opening 81 completely covering the cylindrical opening 31. Moreover, the light-output opening 81 may be further provided with an anti-reflection layer 90 which is disposed on the N-type Bragg band-pass reflection layer 70 to form the light-output opening 81, so that the light output of laser is increased as the transmittance is increased.

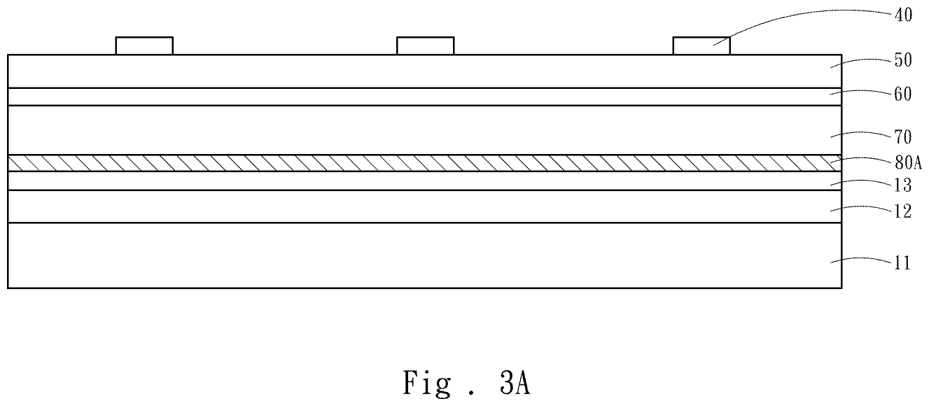

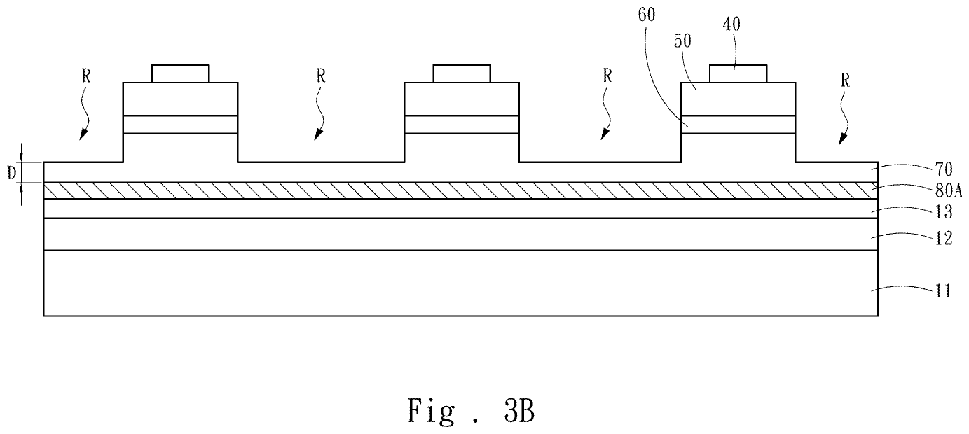

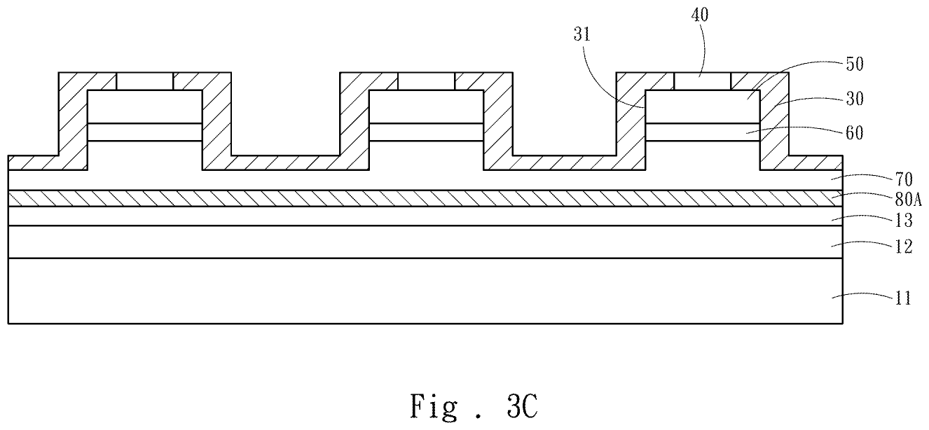

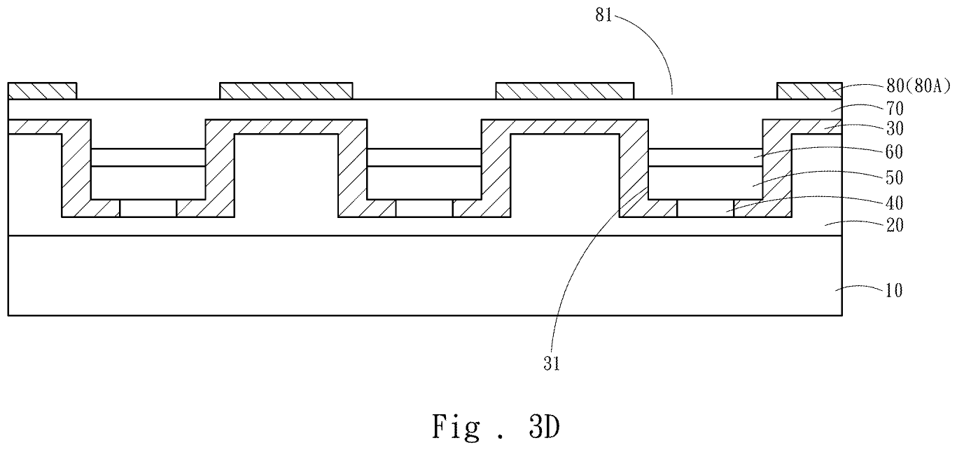

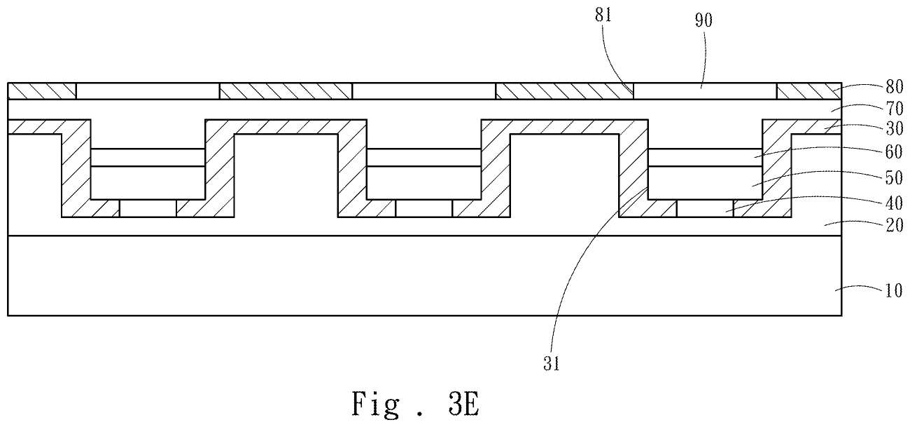

Referring to FIGS. 3A, 3B, 3C, 3D, and FIG. 3E show a manufacturing flowchart of the present invention. First, as shown in FIG. 3A, a desired semiconductor epitaxial structure is grown by using a thin film process. The semiconductor epitaxial structure comprises a semiconductor substrate 11 such as gallium arsenide, a buffer layer 12, an etching stop layer 13, an N-type semiconductor contact layer 80A, the N-type Bragg band-pass reflection layer 70, the diode light-emitting layer 60, the P-type Bragg reflection layer 50 and the P-type electrode 40 at the local position.

Then, as shown in FIG. 3B, the diode light-emitting layer 60 and the P-type Bragg reflection layer 50 at a specified area R are removed by etching. The N-type Bragg band-pass reflection layer 70 is continuously etched and retained for a predetermined thickness D in the specified area.

Next, as shown in FIG. 3C, the galvanic isolation layer 30 is deposited and the P-type electrode 40 is exposed. Meanwhile, the cylindrical opening 31 is formed. The galvanic isolation layer 30 covers the N-type Bragg band-pass reflection layer 70, the diode light-emitting layer 60 and the P-type Bragg reflection layer 50. Further, the diode light-emitting layer 60, the P-type Bragg reflection layer 50 and the P-type electrode 40 are located at the cylindrical opening 31.

Subsequently, as shown in FIG. 3D, the P-type electrode 40 inversely covers and is adhered to the thermally-conductive and electrically-conductive substrate 10 by the bonding layer 20, the semiconductor substrate 11, the buffer layer 12, the etching stop layer 13 and portion of the N-type semiconductor contact layer 80A as shown in FIG. 3A are removed by an etching process to form the light-output opening 81, and the N-type electrode 80 is formed by the N-type semiconductor contact layer 80A which is remaining.

At last, as shown in FIG. 3E, the anti-reflection layer 90 is deposited at the cylindrical opening 31 to complete the structure of the present invention.

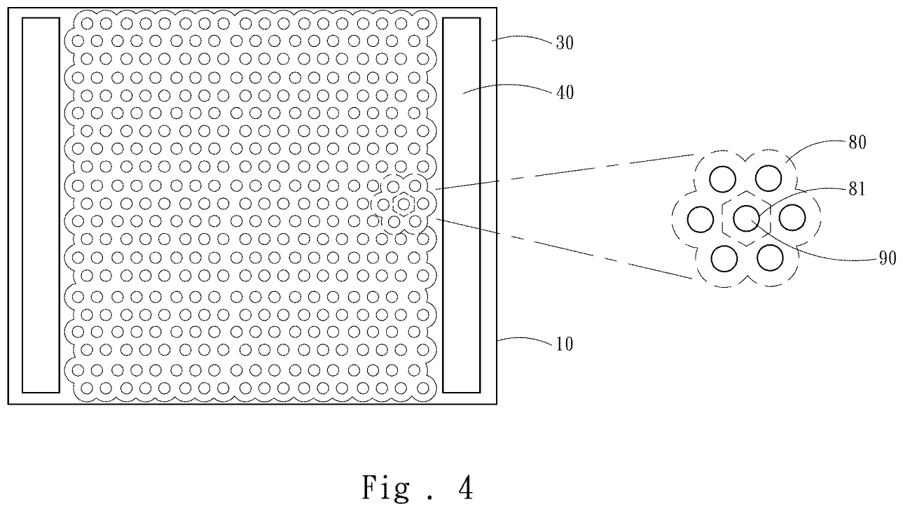

Referring to FIG. 3E and FIG. 4 together, FIG. 4 is a structural schematic diagram of the present invention in plan view. The galvanic isolation layer 30 comprises a plurality of cylindrical openings 31, and the surface-emitting laser structure comprises a corresponding number of the P-type Bragg reflection layers 50, the diode light-emitting layers 60, the N-type Bragg band-pass reflection layers 70, and the light-output openings 81. The bonding layer 20 is exposed from the galvanic isolation layers 30 on two sides of the thermally-conductive and electrically-conductive substrate 10, and is electrically conductive with the P-type electrode 40. The N-type electrode 80 comprises a plurality of light-output openings 81. Each of the plurality of light-output openings 81 comprises a circular shape preferably in plan view. The plurality of light-output openings 81 are arranged in hexagonal closest packing, so that the space of the thermally-conductive and electrically-conductive substrate 10 is utilized sufficiently to increase an area ratio of the plurality of light-output openings 81.

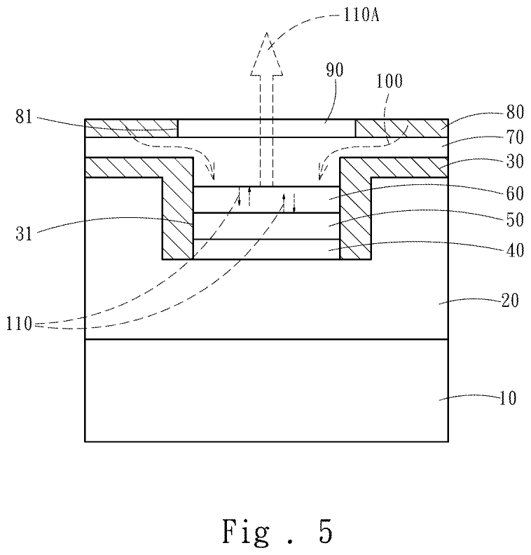

Referring to FIG. 5 again, a schematic diagram of the current direction and the light output of the present invention is shown. As shown in FIG. 5, when a forward bias is supplied between the P-type electrode 40 and the N-type electrode 80, an electron current 100 flows from the N-type electrode 80 to pass through the N-type Bragg band-pass reflection layer 70, then bypasses the galvanic isolation layer 30, and is concentrated to enter the diode light-emitting layer 60. Therefore, the diode light-emitting layer 60 is excited to generate a light 110. The light 110 is emitted toward the periphery after being generated by the diode light-emitting layer 60. The light 110 that is emitted downward is reflected by the P-type Bragg reflection layer 50 and is emitted to the diode light-emitting layer 60. The light 110 in a specific wavelength interval is allowed to pass through the N-type Bragg band-pass reflection layer 70, and has a reflectance of 90-99% and a transmittance of 1-10%. Therefore, the light 110 that is emitted upward is mostly reflected by the N-type Bragg band-pass reflection layer 70 to be emitted on the diode light-emitting layer 60, and then resonated and re-excited with the diode light-emitting layer 60 to regenerate the light 110. Therefore, the light 110A conforming to the specific wavelength interval is emitted through the N-type Bragg band-pass reflection layer 70. In this situation, the response speed and the amount of light emission can be increased, and the use requirement on high brightness is satisfied in the present invention.

Therefore, the present invention at least has the following advantages:

1. when a current input by the N-type electrode passes through the N-type Bragg band-pass reflection layer, the current is concentrated under the constraint of the galvanic isolation layer and passes through the diode light-emitting layer via the cylindrical opening, according to a correspondence relationship in position and size of the cylindrical opening and the light-output opening. Thus, the light-emitting efficiency and the response speed can be increased effectively since a current constraint effect is achieved. Compared with the prior art, a current constraint effect is achieved by the surface-emitting laser structure of the present invention without the use of oxidized metal, thereby the effective light-emitting area is increased.

2. In addition, since the bonding layer is bonded to the thermally-conductive and electrically-conductive substrate, the heat dissipation effect is improved effectively by the high heat conductivity of the thermally-conductive and electrically-conductive substrate, and thus the usage requirements of laser with high power is met.

3. The process yield is improved effectively since oxidized metal is no need to use to adopt a wet oxidation process with large variation in process.

What is claimed is:

1. A surface-emitting laser structure with high heat dissipation, comprising:
a thermally-conductive and electrically-conductive substrate;
a bonding layer disposed on the thermally-conductive and electrically-conductive substrate;
a galvanic isolation layer disposed on the bonding layer, comprising a cylindrical opening;
a P-type electrode disposed in the cylindrical opening and located on the bonding layer;
a P-type Bragg reflection layer disposed on the P-type electrode and located in the cylindrical opening;
a diode light-emitting layer located in the cylindrical opening, and disposed on the P-type Bragg reflection layer;
an N-type Bragg band-pass reflection layer disposed on the diode light-emitting layer, filling the cylindrical opening and covering the galvanic isolation layer;
an N-type electrode disposed on the N-type Bragg band-pass reflection layer, comprising a light-output opening facing the cylindrical opening, a projection of the light-output opening completely covering the cylindrical opening; and
an anti-reflection layer disposed on the N-type Bragg band-pass reflection layer, covering the N-type electrode to form the light-output opening.

2. The surface-emitting laser structure with high heat dissipation according to claim 1, wherein light of a specific wavelength interval is allowed to pass through the N-type Bragg band-pass reflection layer, the N-type Bragg band-pass reflection layer comprises a reflectance of 90-99% and a transmittance of 1-10%.

3. The surface-emitting laser structure with high heat dissipation according to claim 1, wherein the galvanic isolation layer comprises a plurality of cylindrical openings, and the surface-emitting laser structure comprises a corresponding number of the P-type Bragg reflection layers, the diode light-emitting layers, the N-type Bragg band-pass reflection layers, and the light-output openings.

4. The surface-emitting laser structure with high heat dissipation according to claim 3, wherein each of the plurality of light-output openings comprises a circular shape in plan view, and the plurality of light-output openings are arranged in hexagonal closest packing.
